(19) United States
(12) Patent Application Publication
(10) Pub. No.: US 2016/0365528 A1
(43) Pub. Date: Dec. 15, 2016

(54) ORGANIC LIGHT-EMITTING DISPLAY DEVICE, PRODUCTION METHOD THEREOF AND DISPLAY APPARATUS

(71) Applicant: BOE TECHNOLOGY GROUP CO., LTD, Beijing (CN)

(72) Inventor: Hui Tian, Beijing (CN)

(21) Appl. No.: 14/771,671

(22) PCT Filed: Oct. 28, 2014
(86) PCT No.: PCT/CN2014/089675

§ 371 Date: Aug. 31, 2015

(30) Foreign Application Priority Data
Aug. 14, 2014 (CN) 201410398412.5

(51) Int. Cl. H01L 51/50; H01L 51/52; H01L 51/56

(52) U.S. Cl. CPC H01L 51/5088; H01L 51/56; H01L 51/5206

(57) ABSTRACT

This present application discloses an organic light-emitting display device and the production method thereof, and a display apparatus. This organic light-emitting display device comprises an anode, a hole injection layer, a hole transport layer, an organic light-emitting layer, an electron injection layer, an electron transport layer and a cathode, wherein a hole buffering layer is provided between the anode and the hole injection layer or between the hole injection layer and the hole transport layer to limit the injection of excess holes into the organic light-emitting layer. This disclosure further discloses an organic light-emitting display device and the production method thereof, and a display apparatus. In this disclosure, the injection of excess holes into an organic light-emitting layer may be effectively limited by adding a polymer as a hole buffering layer between an anode and a hole injection layer or between a hole injection layer and a hole transport layer to achieve the balanced injection of electrons and holes in an organic light-emitting layer. Therefore, while this disclosure improves the properties such as efficiency, brightness, or the like of the organic light-emitting device, it also is possible to effectively reduce the working voltage of the organic light-emitting device and in turn the energy consumption of the organic light-emitting device.

### FIELD OF THE INVENTION

This disclosure belongs to the field of display technology, particularly to an organic light-emitting display device (OLED) and the production method thereof, and a display apparatus.

### BACKGROUND OF THE INVENTION

With the development of multimedia techniques and continuous improvement of the informationization level, the requirements for the properties of flat-panel display apparatuses are increasingly higher. Compared to liquid crystal displays, organic electroluminescent displays have a range of advantages such as spontaneous light emission, low-voltage DC actuation, being fully solidified, wide view angle, abundant colors, or the like. Meanwhile, the organic electroluminescent display does not require back-lighting sources, and has a large view angle, a low energy consumption, and a response speed up to 1000 times that of a liquid crystal display. However, its production cost is lower than a liquid crystal display having the same resolution. Therefore, organic electroluminescent displays have a wider prospect for application.

An organic electroluminescence light-emitting device (OLED) is a display apparatus in which electrical energy is converted to optical energy in an organic material, and a conventional structure of an OLED comprises an anode, a luminescent material layer, and a cathode, stacked in this order. Its principle of light emission is that holes and electrons injected from an anode and a cathode are recombined in a luminescent material layer to generate excitons thereby achieving light emission.

The internal quantum efficiency of an OLED device mainly depends on efficiencies of injection, transport, and recombination of carriers, while it is significantly affected by injection balance of carriers. As for most of OLED devices having hole injection layers, a hole has a smaller injection potential barrier with respect to an electron, thereby leading to redundant accumulation to a light-emitting layer. The speed at which excitons are formed by holes and electrons is allowed to be reduced, thereby leading to the reduction of light-emission efficiency and brightness of OLED display devices.

In order to address the problem described above and to obtain a high-performance light emitting device, a hole barrier layer is typically added at the side of the cathode in the prior art to increase the limit on carriers and excitons, thereby increasing the possibility of exciton recombination and the properties of the device. However, since the mobility of electrons in a hole barrier layer is very low, the hole barrier layer significantly increases the working voltage of devices while improving the properties thereof, thereby leading to the increase of energy consumption of OLED devices.

### SUMMARY OF THE INVENTION

In order to ensure the recombination balance of carriers and to enhance the properties, such as light-emission efficiency, or the like, of OLED devices, this disclosure provides an organic light-emitting display device and the production method thereof and a display apparatus, wherein the injection of excess holes into a light-emitting layer may be effectively limited by adding a polymer PEO as a hole buffering layer between an anode and a hole injection layer or between a hole injection layer and a hole transport layer, to achieve the balanced injection of electrons and holes in an organic light-emitting layer, thereby improving the properties, such as light-emission efficiency, brightness, or the like, of the organic light-emitting display device.

According to an aspect of this disclosure, there is proposed an organic light-emitting display device, comprising an anode 2, a hole injection layer 3, a hole transport layer 5, an organic light-emitting layer 6, an electron injection layer 7, an electron transport layer 8 and a cathode 9, wherein a hole buffering layer 4 is provided between the anode 2 and the hole injection layer 3 or between the hole injection layer 3 and the hole transport layer 5 to limit the injection of excess holes into the organic light-emitting layer 6.

According to another aspect of this disclosure, there is further proposed a display apparatus, comprising the organic light-emitting display device as described above.

According to still another aspect of this disclosure, there is further proposed a production method for an organic light-emitting display device, comprising the steps of:

forming an anode 2 on a substrate 1;

forming a hole injection layer 3 on the anode 2;

forming a hole transport layer 5 on the hole injection layer 3;

forming a hole buffering layer 4 between the anode 2 and the hole injection layer 3 or between the hole injection layer 3 and the hole transport layer 5 to limit the injection of excess holes into an organic light-emitting layer 6; and

forming an organic light-emitting layer 6, an electron injection layer 7, an electron transport layer 8 and a cathode 9 sequentially on the hole transport layer 5.

Compared to the prior art, this disclosure has the advantageous effect that, since PEO has good insulation property and a matched energy level, when it is used as a hole buffering layer, holes are mainly injected by tunneling. The injection of excess holes into a light-emitting layer may be effectively limited by adding a polymer PEO as a hole buffering layer between an anode and a hole injection layer or between a hole injection layer and a hole transport layer, to achieve the balanced injection of electrons and holes in an organic light-emitting layer, thereby improving overall properties of the organic light-emitting device, for example, properties such as light-emission efficiency, brightness, or the like, of the organic light emitting device. Furthermore, by adding a PEO hole buffering layer at the anode side, the defect that electron injection of the hole barrier layer at the side of the cathode is limited in the traditional technology is prevented, and thereby it is possible to effectively reduce the working voltage of the OLED device and in turn the energy consumption of the OLED device.

### BRIEF DESCRIPTION OF THE DRAWINGS

FIG. 1 is a structural schematic diagram of an organic light-emitting display device of an Example according to this disclosure;

FIG. 2 is a flow chart of a production method for an organic light-emitting display device of an Example according to this disclosure.

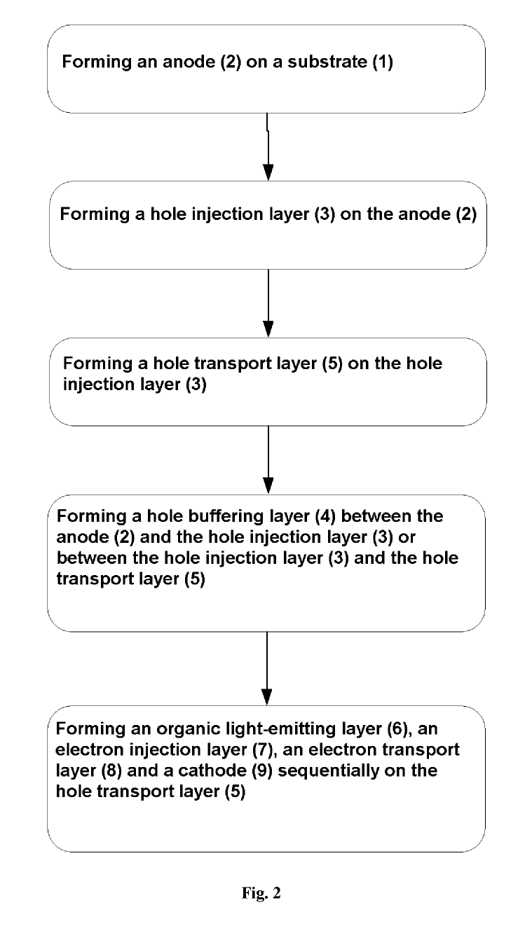

### DETAILED DESCRIPTION OF THE INVENTION

In order to enable the objects, technical solutions, and advantages of this disclosure to be more obvious and clear, this disclosure will be further illustrated in details in conjunction with specific embodiments and with reference to figures.

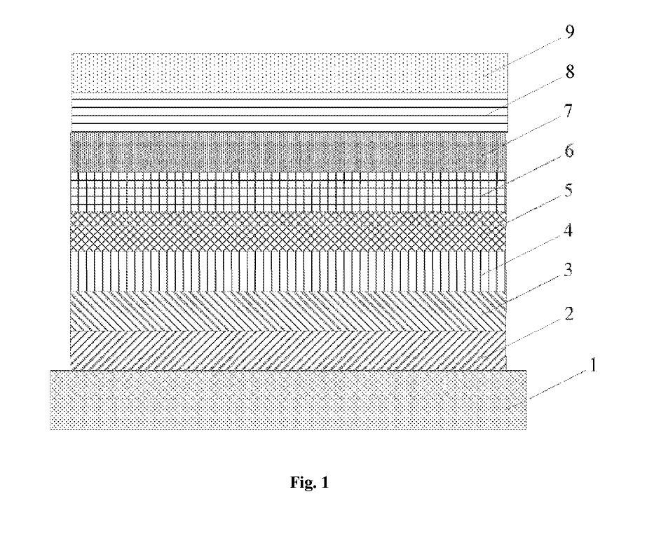

According to an aspect of this disclosure, there is provided an organic light-emitting display device as shown by FIG. 1, comprising an anode 2, a hole injection layer 3, a hole transport layer 5, an organic light-emitting layer 6, an electron injection layer 7, an electron transport layer 8 and a cathode 9, and a hole buffering layer 4 is provided between the anode 2 and the hole injection layer 3 or between the hole injection layer 3 and the hole transport layer 5, wherein:

The hole buffering layer 4 is produced from a polymer. Since the polymer has good insulation property and a matched energy level, when it is used as a hole buffering layer, holes are mainly injected by tunneling. The injection of excess holes into the organic light-emitting layer 6 may be effectively limited by adding a polymer as a hole buffering layer 4 between an anode 2 and a hole injection layer 3 or between a hole injection layer 3 and a hole transport layer 5, to achieve the balanced injection of electrons and holes in the organic light-emitting layer 6, thereby improving the properties, such as light-emission efficiency, brightness, or the like, of the organic light-emitting display device while effectively reducing the working voltage of the organic light-emitting display device.

Preferably, the polymer is polyethylene oxide (PEO), having a molecular formula of H—(—OCH₂CH₂—)ₙ—OH, wherein n is the number of the repeating unit —OCH₂CH₂—. According to certain preferred embodiments of this disclosure, the polyethylene oxide has a weight average molecular weight of 150000-250000, preferably 180000-220000, and more preferably 190000-210000. The commercially available sources of the polyethylene oxide include polyethylene oxide resins produced by Dow Chemical Company, United States or Sumitomo Chemical Co., Ltd., Japan, having a weight average molecular weight of 200000.

In an embodiment of this disclosure, a PEO thin film is formed by a process such as coating or the like to obtain a hole buffering layer 4, wherein the PEO thin film is preferably prepared by spin-coating an aqueous PEO solution.

Preferably, the hole buffering layer 4 has a thickness of 0.1-1 nm, 0.2-0.7 nm, and more preferably 0.4-0.5 nm.

In this case, the anode 2 is produced from a material having a high work function and light transmittability, preferably a stable, light transmittable indium tin oxide (ITO) transparent conductive film having a high work function of 4.5 eV-5.3 eV.

In an embodiment of this disclosure, an ITO anode is formed by the magnetron sputtering method.

Optionally, the ITO transparent conductive film has a Rs<20 Ω□.

The anode 2 has a thickness of 50-100 nm.

In this case, the hole transport layer 5 is produced from an organic material such as PEDOT:PSS, which consists of two materials including PEDOT, which is the polymer of EDOT (3,4-ethylenedioxythiophene monomer), and PSS, which is polystyrenesulfonate, wherein the PEDOT:PSS thin film has a thickness of 20-60 nm.

Preferably, the organic light-emitting layer 6 is produced from aluminum 8-hydroxyquinolinate (A1Q3).

Optionally, the organic light-emitting layer 6 has a thickness of 50-150 nm.

In this case, the electron injection layer 7 is produced from an organic metal complex or an inorganic matter such as lithium fluoride (LiF).

Optionally, the electron injection layer 7 has a thickness of 0.1-1.2 nm.

In this case, the electron transport layer 8 is produced from an organic material different from the one for producing the hole transport layer 5, such as a fluorochrome compound.

The electron transport layer 8 has a thickness of 1-10 nm.

In this case, the cathode 9 is produced from a conductive material. Preferably, the conductive material is either a metal material having a low work function, such as aluminum, silver, calcium, indium, lithium, magnesium, or the like, or a composite metal material having a low work function, such as magnesium silver, or the like.

Optionally, the cathode 9 has a thickness of 50-150 nm.

In this case, the organic light-emitting display device further comprises a substrate 1, on which the anode 2 is formed.

Optionally, the materials for producing the substrate 1 include glass, silicon wafer, quartz, plastic, silicon wafer, or the like, and preferably glass.

According to another aspect of this disclosure, there is further proposed a display apparatus, comprising the organic light-emitting display device as described above.

According to still another aspect of this disclosure, there is further proposed a production method for an organic light-emitting display device, comprising the following steps (1)-(5).
(1) Forming an anode 2 on a substrate 1;

Optionally, the materials for producing the substrate 1 include glass, silicon wafer, quartz, plastic, silicon wafer, or the like, and preferably glass.

In this case, the anode 2 is produced from a material having a high work function and light transmittability, preferably a stable, light transmittable indium tin oxide (ITO) transparent conductive film having a high work function of 4.5 eV-5.3 eV.

In an embodiment of this disclosure, an ITO anode is formed by the magnetron sputtering method.

Optionally, the ITO transparent conductive film has a Rs<20 Ω□.
(2) Forming a hole injection layer 3 on the anode 2;
(3) Forming a hole transport layer 5 on the hole injection layer 3;

In this case, the hole transport layer 5 is produced from an organic material, such as PEDOT:PSS, which consists of two materials including PEDOT, which is the polymer of EDOT (3,4-ethylenedioxythiophene monomer), and PSS, which is polystyrenesulfonate, wherein the PEDOT:PSS thin film has a thickness of 20-60 nm.
(4) Forming a hole buffering layer 4 between the anode 2 and the hole injection layer 3 or between the hole injection layer 3 and the hole transport layer 5;

In this case, the hole buffering layer 4 is produced from a polymer, and since the polymer has good insulation property and a matched energy level, when it is used as a hole buffering layer, holes are mainly injected by tunneling. The injection of excess holes into an organic light-emitting layer 6 may be effectively limited by adding a polymer as a hole buffering layer 4 in the anode 2 and the hole transport layer 5, to achieve the balanced injection of electrons and holes in the organic light-emitting layer 6, thereby improving the properties, such as light-emission efficiency, brightness, or the like, of the organic light-emitting display device while effectively reducing the working voltage of the organic light-emitting display device.

Preferably, the polymer is polyethylene oxide (PEO), having a molecular formula of H—(—OCH₂CH₂—)ₙ—OH, wherein n is the number of the repeating unit —OCH₂CH₂—. According to certain preferred embodiments of this disclosure, the polyethylene oxide has a weight average molecular weight of 150000-250000, preferably 180000-220000, and more preferably 190000-210000. The commercially available sources of the polyethylene oxide include polyethylene oxide resins produced by Dow Chemical Company, United States or Sumitomo Chemical Co., Ltd., Japan, having a weight average molecular weight of 200000.

In an embodiment of this disclosure, a PEO thin film is formed by a process such as coating or the like to obtain a hole buffering layer 4, wherein the PEO thin film is preferably prepared by spin-coating an aqueous PEO solution.

Preferably, the hole buffering layer 4 has a thickness of 0.1-1 nm, preferably 0.2-0.7 nm, and more preferably 0.4-0.5 nm.
(5) Forming an organic light-emitting layer 6, an electron injection layer 7, an electron transport layer 8 and a cathode 9 sequentially on the hole transport layer 5.

Optionally, the organic light-emitting layer 6 has a thickness of 50-150 nm.

In this case, the electron injection layer 7 is produced from an organic metal complex or an inorganic matter such as lithium fluoride (LiF).

Optionally, the electron injection layer 7 has a thickness of 0.1-1.2 nm.

In this case, the electron transport layer 8 is produced from an organic material different from the one for producing the hole transport layer 5, such as a fluorochrome compound.

In this case, the cathode 9 is produced from a conductive material. Preferably, the conductive material is either a metal material having a low work function, such as aluminum, silver, calcium, indium, lithium, magnesium, or the like, or a composite metal material having a low work function, such as magnesium silver, or the like.

Optionally, the cathode 9 has a thickness of 50-150 nm.

In an embodiment of this disclosure, a PEDOT:PSS thin film is formed by a process such as coating to obtain a hole transport layer 5; the organic light-emitting layer 6 is formed by vacuum deposition with aluminum 8-hydroxyquinolinate (A1Q3); the electron injection layer 7 is formed by vacuum deposition with lithium fluoride (LiF); and the cathode 9 is formed by vacuum deposition with aluminum (Al).

The method further comprises a step of cleaning the base substrate and performing ultraviolet treatment.

In the tests performed according to the embodiments of this disclosure, the device having the hole buffering layer has a light-emission efficiency of 5.5-5.8 cd/A, a threshold voltage of 4.1-4.3 v, and a brightness of 2500-3000 cd/m², while the standard device without this layer has a light-emission efficiency of 3.1-3.3 cd/A, a threshold voltage of 6.3-6.8 v, and a brightness of 1500-2000 cd/m². It thus can be known that, by introducing a hole buffering layer between the anode and the hole injection layer or between the hole injection layer and the hole transport layer, the object of effectively reducing the working voltage of the OLED device while improving the properties such as light-emission efficiency, brightness, or the like, of the organic light-emitting device can be achieved.

The objects, technical solutions, and advantageous effects of this disclosure are further illustrated in details by the specific embodiments described above. It is to be understood that those described above are merely specific embodiments of this disclosure, but are not intended to limit this disclosure. All of modifications, equivalent replacements, improvements, and the like, which are within the spirit and the principle of this disclosure, should be encompassed in the scope protected by this disclosure.

1. An organic light-emitting display device, comprising
an anode,
a hole injection layer,
a hole transport layer,
an organic light-emitting layer,
an electron injection layer,
an electron transport layer and
a cathode,
wherein a hole buffering layer is provided between the anode and the hole injection layer or between the hole injection layer and the hole transport layer to limit the injection of excess holes into the organic light-emitting layer.

2. The organic light-emitting display device according to claim 1, wherein the hole buffering layer is produced from a polymer.

3. The organic light-emitting display device according to claim 2, wherein the polymer is polyethylene oxide.

4. The organic light-emitting display device according to claim 3, wherein the polyethylene oxide has a weight average molecular weight of 150000 to 250000.

5. The organic light-emitting display device according to claim 1, wherein the hole buffering layer has a thickness of 0.1-1 nm.

6. The organic light-emitting display device according to claim 1, wherein the organic light-emitting display device further comprises a substrate, on which the anode is formed.

7. A display apparatus, comprising the organic light-emitting display device as claimed in claim 1.

8. A production method for an organic light-emitting display device, comprising the steps of:
forming an anode on a substrate;
forming a hole injection layer on the anode;
forming a hole transport layer on the hole injection layer;
forming a hole buffering layer between the anode and the hole injection layer or between the hole injection layer and the hole transport layer to limit injection of excess holes into an organic light-emitting layer; and
forming an organic light-emitting layer, an electron injection layer, an electron transport layer and a cathode sequentially on the hole transport layer.

9. The production method according to claim 8, wherein the hole buffering layer is produced from a polymer.

10. The production method according to, wherein the polymer is polyethylene oxide.

11. The production method according to claim 10, wherein the polyethylene oxide has a weight average molecular weight of 150000 to 250000.

12. The production method according to claim 8, wherein the hole buffering layer has a thickness of 0.1-1 nm.

13. The display apparatus according to claim 7, wherein the hole buffering layer is produced from a polymer.

14. The display apparatus according to claim 13, wherein the polymer is polyethylene oxide.

15. The display apparatus according to claim 14, wherein the polyethylene oxide has a weight average molecular weight of 150000 to 250000.

16. The display apparatus according to claim 7, wherein the hole buffering layer has a thickness of 0.1-1 nm.

17. The display apparatus according to claim 7, wherein the organic light-emitting display device further comprises a substrate, on which the anode is formed.
